(19) United States
(12) Patent Application Publication
(10) Pub. No.: US 2026/0255844 A1
(43) Pub. Date: Aug. 27, 2026

(54) DISPLAY APPARATUS, METHOD OF MANUFACTURING THE DISPLAY APPARATUS, AND ELECTRONIC APPARATUS

(71) Applicant: Samsung Display Co., Ltd., Yongin-si (KR)

(72) Inventors: Seongkeun Kim, Yongin-si (KR); Dongchan Kim, Yongin-si (KR); Youngeun Choi, Yongin-si (KR); Jiyong Choi, Yongin-si (KR)

(21) Appl. No.: 19/548,104

(22) Filed: Feb. 24, 2026

(30) Foreign Application Priority Data
Feb. 25, 2025 (KR) 10-2025-0024584

(51) Int. Cl. H10K 59/80; H10K 59/12; H10K 102/00; H10K 102/10

(52) U.S. Cl. CPC H10K 59/80518; H10K 59/1201; H10K 59/80516; H10K 59/80517; H10K 59/873; H10K 2102/101; H10K 2102/351

(57) ABSTRACT

A display apparatus, a method of manufacturing the display apparatus, and an electronic apparatus are provided. The display apparatus includes a substrate, a pixel electrode on the substrate, a counter electrode on the pixel electrode, and an intermediate layer between the pixel electrode and the counter electrode and including an emission layer, wherein the pixel electrode includes a main electrode layer including silver (Ag) and lithium (Li).

### CROSS-REFERENCE TO RELATED APPLICATION

The present application claims priority to and the benefit of Korean Patent Application No. 10-2025-0024584, filed on Feb. 25, 2025, in the Korean Intellectual Property Office, the entire disclosure of which is incorporated by reference herein.

### BACKGROUND

### 1. Field

Embodiments of the present disclosure relate to a display apparatus, a method of manufacturing the display apparatus, and an electronic apparatus, and for example, to a display apparatus in which the possibility of defects occurring during the manufacturing process may be reduced, a method of manufacturing the display apparatus, and an electronic apparatus.

### 2. Description of the Related Art

Display apparatuses are currently used for various purposes. As thicknesses and weights of display apparatuses decrease, the range of applications for which such display apparatuses may be used has increased. Also, as applications for display apparatuses have diversified, research regarding methods for designing display apparatuses are being undertaken.

A display apparatus may display an image by using a display element including a pixel electrode, a counter electrode, and an emission layer between the pixel electrode and the counter electrode.

The above information disclosed in this Background section is intended to enhance understanding of the background of the disclosure and may contain information that does not constitute prior art.

### SUMMARY

In display apparatuses of the related art, silver (Ag) may be eluted from a layer of the pixel electrode including silver (Ag) to a layer in contact with the silver (Ag) layer of the pixel electrode.

Embodiments of the present disclosure are directed toward a display apparatus in which the possibility of defects occurring during the manufacturing process may be reduced, a method of manufacturing the display apparatus, and an electronic apparatus. However, the embodiments are examples, and do not limit the scope of the disclosure.

Additional aspects will be set forth in part in the description which follows and, in part, will be apparent from the description, or may be learned by practice of the presented embodiments of the disclosure.

According to one or more embodiments, a display apparatus includes a substrate, a pixel electrode arranged on the substrate, a counter electrode arranged on the pixel electrode, and an intermediate layer arranged between the pixel electrode and the counter electrode and including an emission layer, wherein the pixel electrode includes a main electrode layer including silver (Ag) and lithium (Li).

In one or more embodiments, the main electrode layer may include Li in an amount of about 0.05 wt % to about 2.48 wt % based on a total weight of the main electrode layer.

In one or more embodiments, the pixel electrode may further include an auxiliary electrode layer arranged between the main electrode layer and the intermediate layer.

In one or more embodiments, the intermediate layer may further include a hole transport layer arranged between the pixel electrode and the emission layer and an electron transport layer arranged between the emission layer and the counter electrode, and the auxiliary electrode layer may include a transparent conductive oxide.

In one or more embodiments, the display apparatus may further include an organic insulating layer arranged between the substrate and the pixel electrode, wherein the pixel electrode further includes an adhesive auxiliary layer arranged between the main electrode layer and the organic insulating layer, the adhesive auxiliary layer includes a transparent conductive oxide, and the adhesive auxiliary layer is in direct contact with the organic insulating layer.

In one or more embodiments, a thickness of the main electrode layer may be about 600 Å to about 1,300 Å.

In one or more embodiments, the emission layer may be to emit blue light.

In one or more embodiments, the display apparatus may further include an encapsulation layer arranged on the counter electrode and including at least one inorganic encapsulation layer and at least one organic encapsulation layer.

According to one or more embodiments of the present disclosure, a method of manufacturing a display apparatus includes forming a preliminary adhesive auxiliary layer including a transparent conductive oxide on an organic insulating layer arranged on a substrate, forming a preliminary main electrode layer including silver (Ag) and lithium (Li) on the preliminary adhesive auxiliary layer, forming a preliminary auxiliary electrode layer including the transparent conductive oxide on the preliminary main electrode layer, forming a pixel electrode including an adhesive auxiliary layer, a main electrode layer, and an auxiliary electrode layer by patterning the preliminary adhesive auxiliary layer, the preliminary main electrode layer, and the preliminary auxiliary electrode layer, forming a pixel-defining layer defining a pixel opening on the pixel electrode, the pixel opening exposing a central portion of the pixel electrode, forming an intermediate layer including an emission layer on the auxiliary electrode layer, and forming a counter electrode on the intermediate layer.

In one or more embodiments, the forming of the preliminary main electrode layer may include forming the preliminary main electrode layer by co-depositing Ag and Li on the preliminary adhesive auxiliary layer.

In one or more embodiments, the preliminary main electrode layer may include Li in an amount of about 0.05 wt % to about 2.48 wt % based on a total weight of the preliminary main electrode layer.

In one or more embodiments, the intermediate layer may further include a hole transport layer arranged between the pixel electrode and the emission layer and an electron transport layer arranged on the emission layer.

In one or more embodiments, a thickness of the main electrode layer may be about 600 Å to about 1,300 Å.

In one or more embodiments, the emission layer may be to emit blue light.

According to one or more embodiments of the present disclosure, an electronic apparatus includes a processor and a display apparatus controlled or operated by the processor, wherein the display apparatus includes a substrate, a pixel electrode arranged on the substrate, a counter electrode arranged on the pixel electrode, and an intermediate layer arranged between the pixel electrode and the counter electrode and including an emission layer, wherein the pixel electrode includes a main electrode layer including silver (Ag) and lithium (Li).

In one or more embodiments, the main electrode layer may include Li in an amount of about 0.05 wt % to about 2.48 wt % based on a total weight of the main electrode layer.

In one or more embodiments, the pixel electrode may further include an auxiliary electrode layer arranged between the main electrode layer and the intermediate layer.

In one or more embodiments, the intermediate layer may further include a hole transport layer arranged between the pixel electrode and the emission layer and an electron transport layer arranged between the emission layer and the counter electrode, and the auxiliary electrode layer may include a transparent conductive oxide.

In one or more embodiments, the electronic apparatus may further include an organic insulating layer arranged between the substrate and the pixel electrode, wherein the pixel electrode further includes an adhesive auxiliary layer arranged between the main electrode layer and the organic insulating layer, the adhesive auxiliary layer includes a transparent conductive oxide, and the adhesive auxiliary layer is in direct contact with the organic insulating layer.

In one or more embodiments, the emission layer may be to emit blue light.

These and/or other aspects will become apparent and more readily appreciated from the following description of embodiments of the present disclosure, the accompanying drawings, and claims.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1A is a block diagram schematically illustrating an electronic apparatus according to one or more embodiments of the present disclosure;

FIG. 1B shows schematic diagrams illustrating electronic apparatuses according to embodiments of the present disclosure;

FIG. 2 is a schematic plan view of a display apparatus according to one or more embodiments of the present disclosure;

FIG. 3 is an equivalent circuit diagram illustrating a pixel circuit included in the display apparatus of FIG. 2, according to one or more embodiments of the present disclosure;

FIG. 4 is a schematic cross-sectional view of the display apparatus taken along the line I-I′ of FIG. 2, according to one or more embodiments of the present disclosure;

FIG. 5 is a schematic cross-sectional view of the portion A of FIG. 4, according to one or more embodiments of the present disclosure;

FIG. 6 is a graph showing a reflectivity of a single layer in relation to wavelength; and

FIGS. 7 to 14 are schematic cross-sectional views illustrating part of a process of manufacturing the display apparatus of FIG. 4, where FIGS. 7-12 and 14 are each a schematic cross-sectional view of the display apparatus taken along the line I-I′ of FIG. 2, according to one or more embodiments of the present disclosure, and FIG. 13 is a schematic cross-sectional view of the portion B of FIG. 12, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

Because the disclosure may have diverse modified embodiments, embodiments are illustrated in the drawings and are described in the detailed description. An aspect and a characteristic of the disclosure, and a method of accomplishing these may be apparent if (e.g., when) referring to one or more embodiments described with reference to the drawings. The disclosure may, however, be embodied in many different forms and should not be construed as limited to the embodiments set forth herein.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In this specification, the expression “A and/or B” may indicate A, B, or A and B. Also, the expression “at least one of A and B” may indicate A, B, or A and B.

It will be understood that when an element, such as an area, layer, film, region, component, or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present. For example, in the specification, if (e.g., when) a layer, region, component, and/or the like is electrically connected to another layer, region, component, and/or the like, the layer, region, component, and/or the like may be directly electrically connected thereto and/or may be indirectly electrically connected thereto with an intervening layer, region, component, and/or the like therebetween.

In the specification, an x-axis, a y-axis, and a z-axis are not limited to three axes on an orthogonal coordinate system, but may be interpreted in a broad sense including the three axes. For example, the x-axis, the y-axis, and the z-axis may be normal (e.g., perpendicular) to one another, or may represent different directions that are not normal (e.g., perpendicular) to one another.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the terms “use,” “using,” and “used” may be considered synonymous with the terms “utilize,” “utilizing,” and “utilized,” respectively.

When a certain embodiment may be implemented differently, a specific process order may be performed differently from the described order. For example, two consecutively described processes may be performed substantially at the same time or performed in an order opposite to the described order.

Hereinafter, embodiments will be described in more detail with reference to the accompanying drawings, wherein substantially the same or corresponding elements are denoted by the same reference numerals throughout and a repeated description thereof may not be provided. In the drawings, the relative sizes (e.g., including lengths, widths and thicknesses) of elements, layers, and regions may be exaggerated or reduced for clarity. For example, because sizes and thicknesses of elements in the drawings are illustrated for convenience of description, the following embodiments are not limited thereto.

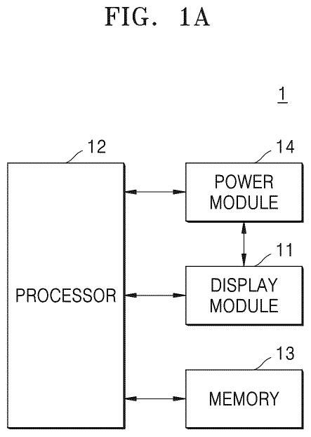

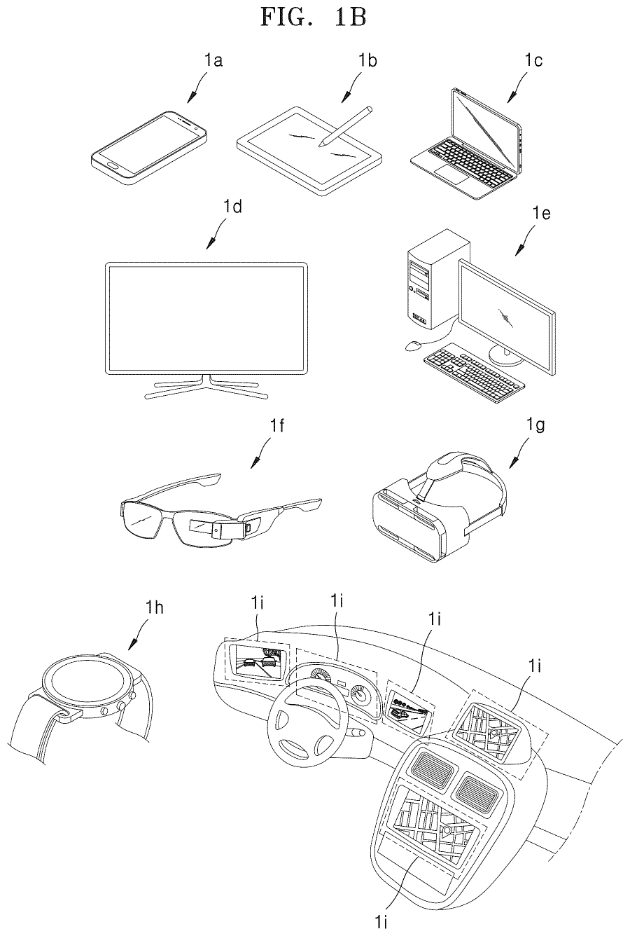

FIG. 1A is a block diagram schematically illustrating an electronic apparatus according to one or more embodiments of the present disclosure. The electronic apparatus 1 according to one or more embodiments may further include a module having other functions in addition to a display module 11. For example, as illustrated in FIG. 1A, the electronic apparatus 1 according to one or more embodiments may include a display module 11, a processor 12, a memory 13, and a power module 14.

The processor 12 may control and/or operate components of the electronic apparatus 1. The processor 12 may include at least one of a central processing unit (CPU), an application processor (AP), a graphics processing unit (GPU), a communication processor (CP), an image signal processor (ISP), and/or a controller.

The memory 13 may store data information necessary for the operation of the processor 12 or the display module 11. When the processor 12 executes an application stored in the memory 13, a data signal and/or an input control signal for an image is transmitted to the display module 11, and the display module 11 may process the received signal and output image information.

The power module 14 may include a power supply module, such as a power adapter or a battery device, and a power conversion module that converts power supplied by the power supply module to generate power for the operation of the electronic apparatus 1.

FIG. 1B shows schematic diagrams illustrating electronic apparatuses 1 according to one or more embodiments of the present disclosure. Referring to FIG. 1B, the electronic apparatuses 1 including the display module 11 may include not only image display electronic apparatuses such as a smart phone 1a, a tablet personal computer (PC) 1b, a laptop 1c, a television (TV) 1d, a desk monitor 1e, and/or the like, but also wearable electronic apparatuses including the display module 11 such as smart glasses 1f, a head mounted display 1g, a smart watch 1h, and/or the like, and vehicle electronic apparatuses 1i including the display module 11 such as a center information display (CID) arranged on a dashboard, a center fascia, or a dashboard of an automobile, a room mirror display, and/or the like.

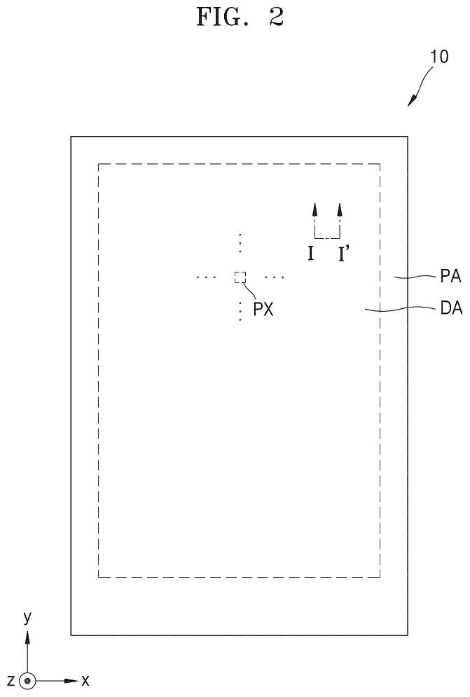

In one or more embodiments, the display module 11 may include the display apparatus 10 (see, e.g., FIG. 2). The display apparatus 10 may be applied to one or more suitable electronic apparatuses 1. For example, the electronic apparatus 1 includes a display apparatus 10, and may further include a module or an apparatus having additional functions in addition to the display apparatus 10. For example, the electronic apparatus 1 may include the display apparatus 10, the processor 12, the memory 13, and the power module 14, and the display apparatus 10 may be controlled and/or operated by the processor 12. Hereinafter, the display apparatus 10 is mainly described.

As illustrated in FIG. 2, the display apparatus 10 may include a display area DA in which a plurality of pixels PX are arranged and a peripheral area PA located outside the display area DA. For example, the peripheral area PA may be around (e.g., may entirely surround) the display area DA.

Each pixel PX of the display apparatus 10 is an area that may be to emit light of a certain color, and the display apparatus 10 may provide an image by using light emitted from the pixels PX. For example, each pixel PX may be to emit red light, green light, or blue light. The display area DA may have a polygonal shape including a rectangle, as illustrated in FIG. 2. For example, the display area DA may have a rectangular shape of which a width is shorter than a height, a rectangular shape of which a width is longer than a height, or a square shape. In one or more embodiments, the display area DA may have one or more suitable shapes, such as an ellipse or a circle.

The peripheral area PA may be a non-display area where pixels PX are not arranged. Drivers, and/or the like for providing electrical signals or power to the pixels PX may be arranged in the peripheral area PA. A plurality of pads to which electronic devices or printed circuit boards may be electrically connected may be arranged in the peripheral area PA. The pads may be apart from each other in the peripheral area PA and may be electrically connected to a printed circuit board or an integrated circuit device.

Hereinafter, an organic light-emitting display apparatus is described as an example of the display apparatus 10 according to one or more embodiments, but the display apparatus of the disclosure is not limited thereto. In one or more embodiments, the display apparatus 10 may be an inorganic light-emitting display apparatus (or an inorganic electroluminescent (EL) display apparatus) or a quantum dot light-emitting display apparatus. For example, an emission layer of a display element included in the display apparatus 10 may include an organic material or an inorganic material. Also, the display apparatus 10 may include an emission layer and a quantum dot layer that is located in a path of light emitted from the emission layer.

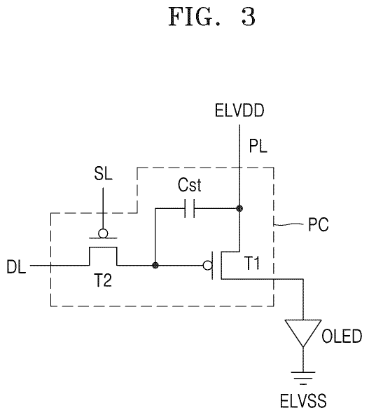

FIG. 3 is an equivalent circuit diagram of the pixel circuit PC included in the display apparatus 10 of FIG. 2, according to one or more embodiments of the present disclosure. The pixel circuit PC may be electrically connected to the display element, and a single display element may correspond to a single pixel. In FIG. 3, an organic light-emitting diode OLED is illustrated as a display element. In one or more embodiments, the display element may be to emit red light, green light, or blue light.

The pixel circuit PC may include a first transistor T1, a second transistor T2, and a storage capacitor Cst. The second transistor T2, which is a switching transistor, may be connected to a scan line SL and a data line DL and may be turned on by a switching signal input from the scan line SL, thereby transmitting a data signal input from the data line DL to the first transistor T1. One end of the storage capacitor Cst may be electrically connected to the second transistor T2 and the other end of the storage capacitor Cst may be electrically connected to the driving voltage line PL, and the storage capacitor Cst may store a voltage corresponding to a difference between a voltage received from the second transistor T2 and a driving power voltage ELVDD supplied to the driving voltage line PL.

The first transistor T1 may be a driving transistor, may be connected to the driving voltage line PL and the storage capacitor Cst, and may be configured to control a magnitude of a driving current flowing from the driving voltage line PL to the organic light-emitting diode OLED, according to a value of a voltage stored in the storage capacitor Cst. The organic light-emitting diode OLED may be to emit light having a certain brightness according to the driving current. A counter electrode of the organic light-emitting diode OLED may receive an electrode power voltage ELVSS.

Although the pixel circuit PC in FIG. 3 includes two transistors and one storage capacitor, the present disclosure is not limited thereto. For example, the number of transistors or the number of storage capacitors may be variously modified according to the design of the pixel circuit PC.

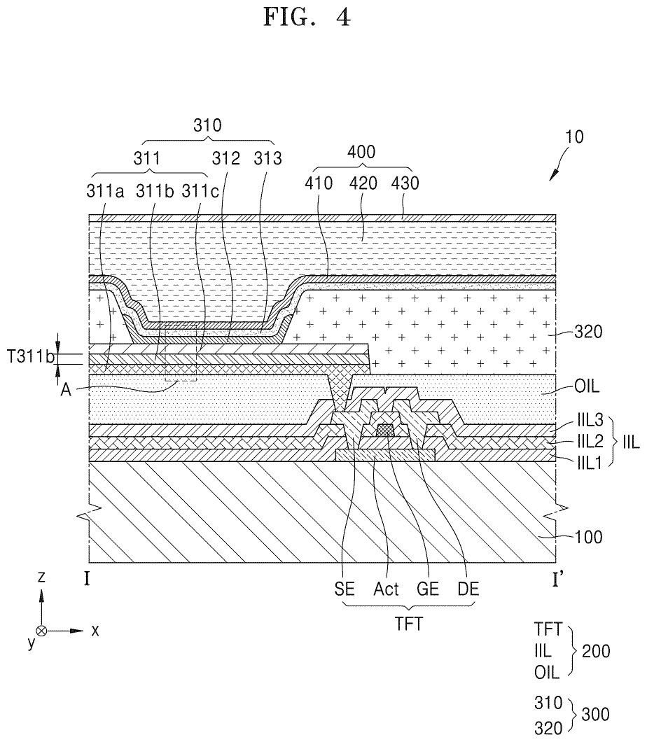

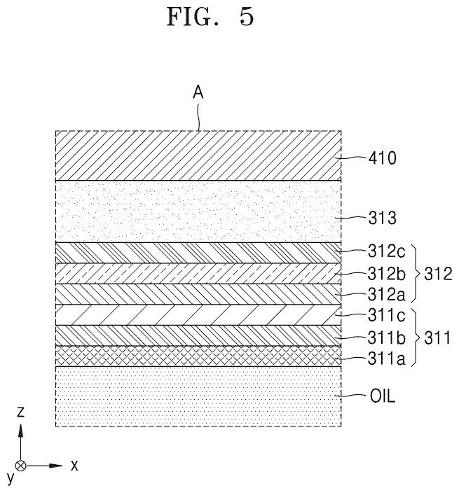

FIG. 4 is a cross-sectional view schematically illustrating a cross-section of the display apparatus 10 taken along the line I-I′ of FIG. 2, according to one or more embodiments of the present disclosure, and FIG. 5 is a cross-sectional view schematically illustrating an enlarged portion A of FIG. 4, according to one or more embodiments of the present disclosure. As will be appreciated by those of ordinary skill in the art, the display apparatus 10 may further include one or more suitable other components in addition to the components illustrated in FIG. 4.

As illustrated in FIG. 4, the display apparatus 10 may include a substrate 100, a pixel circuit layer 200, a display element layer 300, and an encapsulation layer 400. Because the display apparatus 10 includes the substrate 100, it may be understood that the substrate 100 includes the display area DA and the peripheral area PA. For convenience, the following is described assuming that the substrate 100 includes the display area DA and the peripheral area PA.

The substrate 100 may include glass, metal, or polymer resin. In one or more embodiments, the substrate 100 may have flexible or bendable characteristics. In such embodiments, the substrate 100 may include a polymer resin, such as polyether sulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may have a multi-layer structure including two layers and a barrier layer therebetween, each of the two layers including polymer resin and the barrier layer including an inorganic material (e.g., silicon oxide (SiOₓ, where 0<x≤2), silicon nitride (SiₓN_{y}, where 0<x≤3 and 0<y≤4), and silicon oxynitride (SiOₓN_{y})), and one or more suitable modifications may be made.

The pixel circuit layer 200 may be arranged on the substrate 100. The pixel circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, one transistor TFT is illustrated in FIG. 4, which may correspond to the first transistor T1 (see, e.g., FIG. 3) described above.

A semiconductor layer Act may be arranged on the substrate 100. The semiconductor layer Act may include polysilicon. In one or more embodiments, the semiconductor layer Act may include amorphous silicon, an oxide semiconductor, or an organic semiconductor. In one or more embodiments, the semiconductor layer Act may include a channel region, and a source region and a drain region arranged on both sides (e.g., opposite sides) of the channel region.

A gate insulating layer IIL1 may be arranged on the semiconductor layer Act and the substrate 100. The gate insulating layer IIL1 may include an inorganic insulating material such as SiOₓ, SiₓN_{y}, or SiOₓN_{y}. For example, the gate insulating layer IIL1 may have a single-layer or multi-layer structure including the material described above. An insulating layer including an inorganic insulating material may be formed through a method such as chemical vapor deposition. This also applies to one or more embodiments and modifications thereof described in more detail below.

Although FIG. 4 illustrates that the gate insulating layer IIL1 has a shape corresponding to the entire surface of the substrate 100 and a structure in which contact holes are formed in preset portions and/or areas, the present disclosure is not limited thereto. For example, the gate insulating layer IIL1 may be patterned into the same shape as the gate electrode GE.

The gate electrode GE may be arranged on the gate insulating layer IIL1. For example, by disposing the gate insulating layer IIL1 between the semiconductor layer Act and the gate electrode GE, insulation between the semiconductor layer Act and the gate electrode GE may be obtained. The gate electrode GE may overlap the channel region of the semiconductor layer Act. The gate electrode GE may include a low-resistance metal material. In one or more embodiments, the gate electrode GE may include a conductive material including Mo, Al, Cu, Ti, and/or the like, and may have a single-layer or multi-layer structure including the conductive material.

The first interlayer insulating layer IIL2 may be arranged on the gate electrode GE and the gate insulating layer IIL1. The first interlayer insulating layer IIL2 may include an inorganic insulating material such as SiOₓ, SiₓN_{y}, or SiOₓN_{y}. For example, the first interlayer insulating layer IIL2 may have a single-layer or multi-layer structure including the material described above.

The source electrode SE and the drain electrode DE may be arranged on the first interlayer insulating layer IIL2. Each of the source electrode SE and the drain electrode DE may be connected to the semiconductor layer Act through a contact hole formed in the gate insulating layer IIL1 and the first interlayer insulating layer IIL2. At least one of the source electrode SE and/or the drain electrode DE may include a conductive material including Mo, Al, Cu, or Ti, and may have a single-layer or multi-layer structure including the conductive material. In one or more embodiments, at least one of the source electrode SE and/or the drain electrode DE may have a multi-layer structure of Ti/Al/Ti.

However, the present disclosure is not limited thereto. For example, the transistor TFT may have only one of the source electrode SE or the drain electrode DE, or neither of them. For example, one transistor TFT may not include (e.g., may exclude) the drain electrode DE, the other transistor TFT connected to that transistor TFT may not have the source electrode SE, and the semiconductor layers Act of the two transistors may be connected to each other. The above connection structure may have the same effect as if (e.g., when) the transistor TFT includes the source electrode SE, the other transistor TFT includes the drain electrode DE, and the source electrode SE of the transistor TFT is connected to the drain electrode DE of the other transistor TFT.

The second interlayer insulating layer IIL3 may be arranged on the source electrode SE, the drain electrode DE, and the first interlayer insulating layer IIL2. The second interlayer insulating layer IIL3 may include an inorganic insulating material such as SiOₓ, SiₓN_{y}, SiOₓN_{y}. For example, the second interlayer insulating layer IIL3 may have a single-layer or multi-layer structure including the material described above.

An organic insulating layer OIL may be arranged on the second interlayer insulating layer IIL3. The organic insulating layer OIL may serve to generally or substantially planarize an upper portion of the pixel circuit layer 200. The organic insulating layer OIL may include an organic material such as acryl, benzocyclobutene (BCB), or hexamethyldisiloxane (HMDSO). Although the organic insulating layer OIL has a single layer in FIG. 4, one or more suitable modifications may be made.

The display element layer 300 may be arranged on the pixel circuit layer 200. The display element layer 300 may include a display element 310 and a pixel-defining layer 320. For example, the display element 310 may be arranged on the substrate 100. The display element 310 may be electrically connected to the transistor TFT. The display element 310 may be, for example, an organic light-emitting diode including a pixel electrode 311, a counter electrode 313, and an intermediate layer 312 arranged therebetween and including an emission layer. The display element 310 being electrically connected to the transistor TFT may be understood as the pixel electrode 311 of the organic light-emitting diode being electrically connected to the transistor TFT.

For example, the pixel electrode 311 may be arranged on the substrate 100. The pixel electrode 311 may be electrically connected to the transistor TFT by contacting either the source electrode SE or the drain electrode DE through a contact hole formed in the second interlayer insulating layer IIL3 and the organic insulating layer OIL. The pixel electrode 311 may include a reflective layer including silver (Ag), magnesium (Mg), aluminum (AI), platinum (Pt), palladium (Pd), gold (Au), nickel (Ni), neodymium (Nd), iridium (Ir), chromium (Cr), or a compound thereof. for example, the pixel electrode 311 may include a main electrode layer 311b including silver (Ag), and the main electrode layer 311b may further include lithium (Li). For example, the main electrode layer 311b may include Ag and Li. A detailed description of the main electrode layer 311b of the pixel electrode 311 is described in more detail below.

The pixel-defining layer 320 may cover an edge of the pixel electrode 311. The pixel-defining layer 320 may include a pixel opening, and the pixel opening may overlap the pixel electrode 311. For example, the pixel opening may expose a central portion of the pixel electrode 311 of the display element 310, and at least a portion of the intermediate layer 312 of the display element 310 may be located in the pixel opening. The emission area of light emitted from the display element 310 may be defined by the pixel opening.

In one or more embodiments, as shown in FIG. 4, the pixel-defining layer 320 may increase a distance between an edge of the pixel electrode 311 and the counter electrode 313 above the pixel electrode 311. Accordingly, arcs and/or the like may be prevented or the likelihood thereof may be reduced from occurring at the edge of the pixel electrode 311. The pixel-defining layer 320 may include an organic material such as polyimide or HMDSO. In one or more embodiments, the pixel-defining layer 320 may include a light-blocking material.

The counter electrode 313 may be arranged on the pixel electrode 311. The counter electrode 313 may be integrally provided over the entire surface of the display apparatus 10, and thus may be commonly provided at (in) a plurality of display elements 310. For example, the counter electrode 313 may be integrally provided across the plurality of display elements 310. Accordingly, the counter electrode 313 may correspond to the plurality of pixel electrodes 311. The counter electrode 313 may include a light-transmitting conductive layer formed of ITO, indium (III) oxide (In203), or IZO, and may include a semi-transmissive layer including a metal such as Al or Ag. For example, the counter electrode 313 may be a semi-transmissive layer including Mg or Ag.

The intermediate layer 312 including the emission layer may be arranged between the pixel electrode 311 and the counter electrode 313. For example, as illustrated in FIG. 5, the intermediate layer 312 may include an emission layer 312b, and the intermediate layer 312 may further include a hole transport layer 312a and an electron transport layer 312c. For example, the intermediate layer 312 may include the hole transport layer 312a, the emission layer 312b, and the electron transport layer 312c.

The emission layer 312b may be to emit red light, green light, or blue light. The emission layer 312b may include a host material and a dopant material. The emission layer 312b may be formed by using a phosphorescent or fluorescent light-emitting material as a dopant in the host material. The emission layer 312b may be formed by including a thermally activated delayed fluorescence (TADF) dopant in the host material. The color of light emitted by the emission layer 312b may be determined by a combination of the host material and the dopant material.

Generally available and/or generally utilized materials may be used as the host material and the dopant material of the emission layer 312b. For example, the host material of the emission layer 312b may include at least one of a fluoranthene derivative, a pyrene derivative, an arylacetylene derivative, an anthracene derivative, a fluorene derivative, a perylene derivative, and/or a chrysene derivative. For example, the dopant material of the emission layer 312b may include at least one of a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), perylene and/or derivatives thereof (e.g., 2, 5, 8, 11-Tetra-t-butylperylene (TBP)), and/or pyrene and/or derivatives thereof (e.g., 1,1-dipyrene, 1,4-dipyrenylbenzene, 1,4-Bis(N, N-Diphenylamino)pyrene) and N1,N6-di(naphthalen-2-yl)-N1,N6-diphenylpyrene-1,6-diamine). However, the present disclosure is not limited thereto.

Functional layers may be arranged below and above the emission layer 312b. For example, the hole transport layer 312a may be arranged between the pixel electrode 311 and the emission layer 312b, and the electron transport layer 312c may be arranged between the emission layer 312b and the counter electrode 313. Each of the hole transport layer 312a and the electron transport layer 312c may be integrally formed across the plurality of pixel electrodes 311, or may be patterned to respectively correspond to each of the plurality of pixel electrodes 311.

The hole transport layer 312a may include a hole transport material, and the hole transport material may include at least one of a carbazole-based derivative such as N-penylcarbazole, polyvinyl carbazole, a fluorene-based derivative, a tripenylamine-based derivative such as N,N′-bis(3-methylphenyl)-N,N′-diphenyl-[1,1-biphenyl]-4,4′-diamine (TPD), 4,4′,4″-tris(N-carbazolyl)triphenylamine (TCTA), and/or the like, N,N′-di(naphthalene-1-yl)-N,N′-diphenyl-benzidine (NPB), 4,4′-Cyclohexylidene bis[N,N-bis(4-methylphenyl)benzenamine](TAPC), 4,4′-Bis[N,N′-(3-tolyl)amino]-3,3′-dimethylbiphenyl (HMTPD), 1,3-Bis(N-carbazolyl)benzene (mCP), 9-(4-tert-Butylphenyl)-3,6-bis(triphenylsilyl)-9H-carbazole (CzSi), and/or 4,4′,4″-[tris(3-methylphenyl)phenylamino]triphenylamine (m-MTDATA). However, the present disclosure is not limited thereto. In one or more embodiments, the hole transport layer 312a may further include TCTA.

The electron transport layer 312c may include an electron transport material, and the electron transport material may include a triazine-based compound or an anthracene-based compound. For example, the electron transport material may include at least one of Tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tris(1-phenyl-1H-benzo[d]imidazol-2-yl)benzene (TPBi), 2,9-Dimethyl-4,7-diphenyl-1,10-phenanthroline (BCP), 4,7-Diphenyl-1, 10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAIq), berylliumbis(benzoquinolin-10-olate (Bebq2), 9,10-di(naphthalene-2-yl)anthracene (ADN), diphenyl(4-(triphenylsilyl)phenyl)phosphine oxide (TSPO1), and/or 2,4,6-Tris(3-(pyrimidin-5-yl)phenyl)-1,3,5-triazine (TPM-TAZ). However, the present disclosure is not limited thereto. In one or more embodiments, the electron transport layer 312c may further include at least one of lithium quinolate (LiQ) and/or 2,4,6-tri([1,1′-biphenyl]-3-yl)-1,3,5-triazine (T2T).

In one or more embodiments, the intermediate layer 312 may further include an electron injection layer. The electron injection layer may be arranged between the electron transport layer 312c and a counter electrode 313, and the electron injection layer may include ytterbium (Yb). Because the work function of Yb is approximately 2.60 eV, an electron injection layer including Yb may facilitate the injection of electrons or anions from the counter electrode 313 to the intermediate layer 312.

Because the display element 310 may be easily damaged by moisture or oxygen from the outside, the encapsulation layer 400 may cover the display element 310 to protect the display element 310. The encapsulation layer 400 may include at least one inorganic encapsulation layer and at least one organic encapsulation layer. For example, as illustrated in FIG. 4, the encapsulation layer 400 may include a first inorganic encapsulation layer 410, an organic encapsulation layer 420, and a second inorganic encapsulation layer 430.

The first inorganic encapsulation layer 410 may cover the counter electrode 313 and may include SiOₓ, SiₓN_{y}, and/or SiOₓN_{y}. Other layers such as a capping layer may be arranged between the first inorganic encapsulation layer 410 and the counter electrode 313. Because the first inorganic encapsulation layer 410 is formed along the structure therebelow, the upper surface of the first inorganic encapsulation layer 410 may not be planarized, as shown in FIG. 4. The organic encapsulation layer 420 covers the first inorganic encapsulation layer 410, and unlike the first inorganic encapsulation layer 410, the upper surface of the organic encapsulation layer 420 may be approximately or substantially planarized. The organic encapsulation layer 420 may include at least one material selected from a group consisting of polyethylene terephthalate, polyethylene naphthalate, polycarbonate, polyimide, polyethylene sulfonate, polyoxymethylene, polyarylate, and hexamethyldisiloxane. The second inorganic encapsulation layer 430 covers the organic encapsulation layer 420 and may include SiOₓ, SiₓN_{y}, and/or SiOₓN_{y}.

As such, because the encapsulation layer 400 includes the first inorganic encapsulation layer 410, the organic encapsulation layer 420, and the second inorganic encapsulation layer 430, through the above multilayer structure, even if (e.g., when) a crack occurs in the encapsulation layer 400, the crack may be prevented or the likelihood of the crack being connected across the first inorganic encapsulation layer 410 and the organic encapsulation layer 420 or being connected across the organic encapsulation layer 420 and the second inorganic encapsulation layer 430 may be reduced. To this end, it is possible to prevent, minimize, or reduce the formation of a path through which moisture or oxygen from the outside may penetrate into the display apparatus 10.

The pixel electrode 311 may include a reflective layer including Ag, Mg, Al, Pt, Pd, Au, Ni, Nd, Ir, Cr, or a compound thereof. For example, the pixel electrode 311 may include the main electrode layer 311b, and the main electrode layer 311b may include Ag and Li. For example, the main electrode layer 311b may be a layer including Ag doped with a small amount of Li.

Light emitted by the emission layer 312b may proceed in one or more suitable directions. For example, some of the light emitted by the emission layer 312b may travel in a direction from the emission layer 312b to the substrate 100 (e.g., in a−z direction), and some of the light emitted by the emission layer 312b may travel in a direction from the emission layer 312b to the encapsulation layer 400 (e.g., in a +z direction). The main electrode layer 311b may act as a reflective layer that reflects light proceeding from the emission layer 312b to the substrate 100 (e.g., in the −z direction). For example, because the main electrode layer 311b includes Ag, light proceeding from the emission layer 312b to the substrate 100 (e.g., in the −z direction) may be reflected and allowed to proceed toward the encapsulation layer 400 (e.g., in the +z direction). Accordingly, light efficiency of the display apparatus 10 may be improved.

When a first layer includes only Ag and a second layer is in contact with the first layer, Ag of the first layer may be eluted at an interface between the first layer and the second layer. In some instances, gas used in the formation process of the second layer may remain in the second layer. That is, residual gas may exist in the second layer. At the interface between the first layer and the second layer, Ag in the first layer may react with the residual gas in the second layer. Ag in the first layer that reacts with the residual gas in the second layer may move to the second layer. Thus, Ag in the first layer may be eluted.

For example, as illustrated in FIG. 4, several layers may be positioned above and below the main electrode layer 311b, and a side surface of the main electrode layer 311b may be covered by the pixel-defining layer 320. Some gas used in the formation process of the above layers may remain in the layers in contact with the main electrode layer 311b. For example, gas such as hydrogen sulfide (H₂S), hydrogen fluoride (HF), or hydrogen chloride (HCl) may remain in the layers in contact with the main electrode layer 311b. For example, residual gas may exist in the layers in contact with the main electrode layer 311b.

When the main electrode layer 311b includes only Ag, Ag of the main electrode layer 311b may react with the residual gas in the layer in contact with the main electrode layer 311b at an interface between the main electrode layer 311b and the layer in contact with the main electrode layer 311b. Ag of the main electrode layer 311b that reacts with the residual gas in the layer in contact with the main electrode layer 311b may move to the layer in contact with the main electrode layer 311b. Thus, Ag of the main electrode layer 311b may be eluted.

However, in the display apparatus 10 according to the one or more embodiments, the main electrode layer 311b may include Ag, and may further include Li. A highly reactive metal, such as a reactive metal (for example Li), included in the main electrode layer 311b, may react with the residual gas in the layer in contact with the main electrode layer 311b at the interface between the main electrode layer 311b and the layer in contact with the main electrode layer 311b. For example, Li instead of Ag may react with the residual gas in the layer in contact with the main electrode layer 311b. Accordingly, Ag of the main electrode layer 311b may not be eluted. Thus, the possibility of defects occurring during the process of manufacturing the display apparatus 10 may be reduced.

In one or more embodiments, the main electrode layer 311b may include Li in an amount of about 0.05 wt % to about 2.48 wt % based on the total weight of the main electrode layer 311b. The main electrode layer 311b may include Ag in an amount of about 97.52 wt % to about 99.95 wt % based on the total weight of the main electrode layer 311b. The content (e.g., amount) of Ag and Li included in the main electrode layer 311b may be measured using a secondary ion mass spectrometer (SIMS), and/or the like. Because measuring the content (e.g., amount) of components of a single layer by using a SIMS is generally available and/or generally utilized by those of ordinary skill in the art, a detailed description thereof may not be provided.

When the main electrode layer 311b includes too little Li, the effect of doping Li may not be sufficient. For example, if (e.g., when) the main electrode layer 311b includes less than 0.05 wt % of Li based on the total weight of the main electrode layer 311b, the effect of doping Li may not be sufficient to prevent or reduce the elution of Ag. Therefore, if (e.g., when) the main electrode layer 311b includes less than 0.05 wt % of Li based on the total weight of the main electrode layer 311b, it may be difficult to reduce Ag elution from the main electrode layer 311b.

When the main electrode layer 311b includes too much Li, light efficiency of the display apparatus 10 may be reduced and/or low. The reflectivity of Li may be less than the reflectivity of Ag. When the main electrode layer 311b includes more than 2.48 wt % of Li based on the total weight of the main electrode layer 311b, the effect of Li of the main electrode layer 311b on the optical characteristics of the main electrode layer 311b may increase. Accordingly, the effect of reflecting light proceeding in the direction (e.g., the −z direction) from the emission layer 312b to the substrate 100 by the main electrode layer 311b may be reduced. Thus, if (e.g., when) the main electrode layer 311b includes more than 2.48 wt % of Li based on the total weight of the main electrode layer 311b, light efficiency of the display apparatus 10 may be reduced and/or low.

In one or more embodiments, a thickness T311b of the main electrode layer 311b may be about 600 Å to about 1,300 Å. When the thickness T311b of the main electrode layer 311b is less than 600 Å, because the thickness T311b of the main electrode layer 311b is small, the main electrode layer 311b may allow light traveling in the direction (e.g., the −z direction) from the emission layer 312b to transmit, without reflecting, to the substrate 100. Thus, if (e.g., when) the thickness T311b of the main electrode layer 311b is less than 600 Å, light efficiency of the display apparatus 10 may be reduced and/or low. When the thickness T311b of the main electrode layer 311b exceeds 1,300 Å, the cost of manufacturing the display apparatus 10 is greater than if (e.g., when) the thickness T311b of the main electrode layer 311b is about 600 Å to about 1,300 Å, but optical characteristics for both cases may be similar. Thus, if (e.g., when) the thickness T311b of the main electrode layer 311b exceeds 1,300 Å, the cost of manufacturing the display apparatus 10 may be inefficient relative to the improvement of the optical characteristics.

In one or more embodiments, the pixel electrode 311 may further include the adhesive auxiliary layer 311a. The adhesive auxiliary layer 311a may be arranged between the main electrode layer 311b and the organic insulating layer OIL. The organic insulating layer OIL may be arranged between the substrate 100 and the pixel electrode 311. For example, the adhesive auxiliary layer 311a may be in direct contact with the main electrode layer 311b and the organic insulating layer OIL. The adhesive auxiliary layer 311a may be arranged below the main electrode layer 311b to improve an adhesive strength between the pixel electrode 311 and a layer (e.g., an organic insulating layer OIL) below the pixel electrode 311.

The adhesive auxiliary layer 311a may include a material different from the material included in the pixel electrode 311. For example, the adhesive auxiliary layer 311a may include a transparent conductive oxide selected while taking into consideration conductivity and adhesive strength. For example, the adhesive auxiliary layer 311a may include at least one of indium tin oxide (ITO), indium zinc oxide (IZO), indium gallium oxide (IGO), and/or indium gallium zinc oxide (IGZO). The thickness of the adhesive auxiliary layer 311a may be less than the thickness of the main electrode layer 311b. For example, the thickness of the adhesive auxiliary layer 311a may be about 20 Å to about 150 Å. For example, the thickness of the adhesive auxiliary layer 311a may be 70 Å.

In one or more embodiments, the pixel electrode 311 may further include the auxiliary electrode layer 311c. The auxiliary electrode layer 311c may be arranged between the main electrode layer 311b and the intermediate layer 312. For example, the auxiliary electrode layer 311c may be arranged between the main electrode layer 311b and the hole transport layer 312a. For example, the auxiliary electrode layer 311c may be in direct contact with the main electrode layer 311b and the hole transport layer 312a. The auxiliary electrode layer 311c may be arranged between the main electrode layer 311b and the hole transport layer 312a to facilitate the injection of holes or cations from the pixel electrode 311 to the intermediate layer 312.

The auxiliary electrode layer 311c may include a material different from the material included in the pixel electrode 311. For example, the auxiliary electrode layer 311c may include a transparent conductive oxide selected while taking into consideration conductivity and work function. For example, the auxiliary electrode layer 311c may include at least one of ITO, IZO, IGO, and/or IGZO. The thickness of the auxiliary electrode layer 311c may be less than the thickness of the main electrode layer 311b. In some embodiments, the thickness of the auxiliary electrode layer 311c may be about 20 Å to about 150 Å. For example, the thickness of the auxiliary electrode layer 311c may be 50 Å.

The work function of the main electrode layer 311b including Ag and Li may be about 4.1 eV to about 4.3 eV, and the work function of the hole transport layer 312a including the above material may be 5.1 eV. The work function of the auxiliary electrode layer 311c including ITO, which is a transparent conductive oxide, may be about 4.8 eV to about 5.0 eV. Accordingly, if (e.g., when) the auxiliary electrode layer 311c is arranged between the main electrode layer 311b and the hole transport layer 312a, the work function difference between the above layers is reduced, thereby facilitating the injection of holes or cations from the pixel electrode 311 to the intermediate layer 312.

In one or more embodiments, the intermediate layer 312 may further include a hole injection layer. In such embodiments, the hole injection layer may be arranged between the pixel electrode 311 and the hole transport layer 312a. The hole transport layer may include a hole injection material. Any suitable material may be used as the hole injection material, and the present disclosure is not limited to the material of the hole injection material.

Table 1 shows a defect rate when manufacturing the display apparatus based on the structure of the pixel electrode. The defect occurrence rate was obtained by manufacturing a plurality of display apparatuses having different pixel electrode structures (e.g., display apparatuses having the pixel electrode structure of Example 1 and display apparatuses having the pixel electrode structure of Comparative Example 1), and then applying a voltage to the manufactured plurality of display apparatuses to identify display apparatuses having display elements that were not driven.

Example 1 includes a pixel electrode in which an adhesive auxiliary layer, a main electrode layer, and an auxiliary electrode layer are sequentially stacked. The adhesive auxiliary layer of Example 1 includes ITO, and a thickness of the adhesive auxiliary layer is 70 Å. The main electrode layer of Example 1 includes Ag and Li, and a thickness of the main electrode layer of Example 1 is 850 Å. The main electrode layer of Example 1 includes 0.5 wt % of Li based on the total weight of the main electrode layer. The auxiliary electrode layer of Example 1 includes ITO, and a thickness of the auxiliary electrode layer is 50 Å.

Comparative Example 1 includes a pixel electrode in which an adhesive auxiliary layer, a main electrode layer, and an auxiliary electrode layer are sequentially stacked. The adhesive auxiliary layer of Comparative Example 1 includes ITO, and a thickness of the adhesive auxiliary layer of Comparative Example 1 is 70 Å. The main electrode layer of Comparative Example 1 includes Ag, and a thickness of the main electrode layer of Comparative Example 1 is 850 Å. The auxiliary electrode layer of Comparative Example 1 includes ITO, and a thickness of the auxiliary electrode layer is 50 Å. Thus, compared to the main electrode layer of Example 1, the main electrode layer of Comparative Example 1 does not include Li. Comparative Example 1 and Example 1 have the same components except for the pixel electrode.

TABLE 1

| | Pixel electrode | Defect rate |
|---|---|---|
| Comparative | ITO (70 Å)/Ag (850 Å)/ITO (50 Å) | 7% |
| Example 1 | | |
| Example 1 | ITO (70 Å)/AgLi (850 Å)/ITO (50 Å) | 0% |

Referring to Table 1, Comparative Example 1, in which the main electrode layer includes Ag but does not include Li, has a defect rate of 7%. In contrast, Example 1, in which the main electrode layer includes Ag and Li, has a defect rate of 0

As described above, when the main electrode layer includes Ag but does not include Li, Ag of the main electrode layer may be eluted. Eluted Ag may contaminate other components of the display apparatus, thereby causing defects in the display apparatus. Therefore, Comparative Example 1 has a defect rate of 7%. In contrast, when the main electrode layer includes Ag and Li, Ag of the main electrode layer may not be eluted. Accordingly, because the eluted Ag does not contaminate other components of the display apparatus, defects in the display apparatus may not be caused or may be reduced. Therefore, Example 1 has a defect rate of 0%. Thus, the possibility of defects occurring during the process manufacturing the display apparatus may be reduced.

In one or more embodiments, the emission layer 312b may be to emit blue light. For example, the emission layers 312b included in at least some of the plurality of display elements 310 may be to emit blue light. Blue light may be in a wavelength band of about 400 nm to about 495 nm. As described above, the emission layer 312b may be formed by using a phosphorescent or fluorescent light-emitting material as a dopant in the host material, and the color of light emitted by the emission layer 312b may be determined by a combination of the host material and the dopant material, and/or the like. For example, the emission layer 312b may be to emit blue light by including a combination of a host material and a dopant material that may be to emit blue light.

The emission layers 312b included in some other ones of the plurality of display elements 310 may be to emit red light or green light. Red light may be in a wavelength band of about 580 nm to about 780 nm, and green light may be in a wavelength band of about 495 nm to about 580 nm.

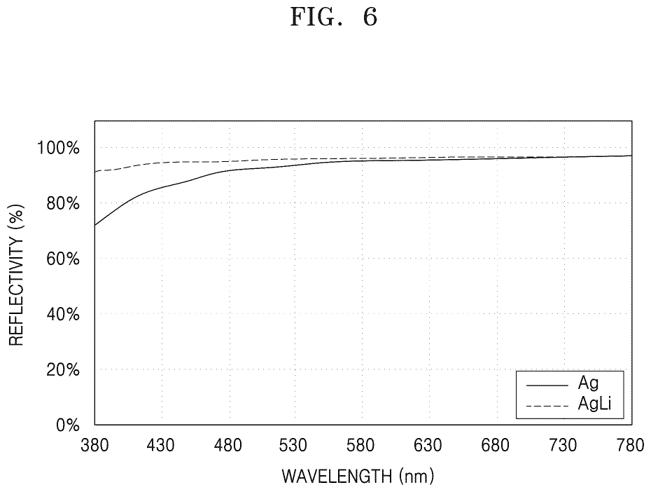

As shown in FIG. 6, which is a graph showing the reflectivity of a layer in relation to wavelength, a layer including Ag and Li may have a higher reflectivity in a short wavelength band compared to a layer including only Ag. In FIG. 6, the solid line indicates the reflectivity of a single layer including only Ag and having a thickness of 850 Å in relation to wavelength. In FIG. 6, the dotted line indicates the reflectivity of a single layer including Ag and Li and having a thickness of 850 Å, Li in an amount of 0.5 wt % being included, in relation to wavelength.

For example, Ag has high reflectivity in the visible light range. However, Ag may have a relatively lower reflectivity in a short wavelength range (e.g., ultraviolet range or blue light range) than in a long wavelength range (e.g., infrared range or red light range). Although the reflectivity of Li alone is less than the reflectivity of Ag alone, when a single layer includes both Ag and Li, Li may serve to compensate for the relatively low reflectivity of Ag in the short wavelength range. Accordingly, compared to when the emission layer 312b emits blue light and the main electrode layer 311b includes only Ag, when the emission layer 312b emits blue light and the main electrode layer 311b includes Ag and Li, the main electrode layer 311b may reflect more light proceeding in a direction (e.g., the −z direction) from the emission layer 312b to the substrate 100. Thus, light efficiency of the display apparatus 10 may be higher and/or improved.

Table 2 shows light efficiency according to the structure of the pixel electrode. The light efficacy was obtained by measuring luminance according to the color of light emitted by the emission layer. Because the structure of the pixel electrode of Example 1 and Comparative Example 1 in Table 2 is substantially identical to the structure of the pixel electrode of Example 1 and Comparative Example 1 in Table 1, redundant descriptions thereof may not be provided.

Light efficiency was obtained by measuring the luminance of each of red light, blue light, and green light after applying a certain range of voltage to Example 1 and Comparative Example 1. The light efficiency of red light was obtained by measuring the luminance of light of which an x-coordinate is approximately 0.687 based on the CIE 1976 color chromaticity diagram, the light efficiency of green light was obtained by measuring the luminance of light of which an x-coordinate is approximately 0.258 based on the CIE 1976 color chromaticity diagram, and the light efficiency of blue light was obtained by measuring the luminance of light of which a y-coordinate is approximately 0.045 based on the CIE 1976 color chromaticity diagram.

TABLE 2

| | | Red light | Green light | Blue light |
|---|---|---|---|---|
| | | Light | Light | Light |
| | Pixel electrode | efficiency | efficiency | efficiency |
| Comparative | ITO (70 Å)/Ag | 64.2 | 157.4 | 156.3 |
| Example 1 | (850 Å)/ITO (50 Å) | | | |
| Example 1 | ITO (70 Å)/AgLi | 64.8 | 168.4 | 175.1 |
| | (850 Å)/ITO (50 Å) | | | |

Referring to Table 2, Comparative Example 1, in which the main electrode layer includes Ag and does not include Li, has a light efficiency of 64.2 for red light. Example 1, in which the main electrode layer includes Ag and Li, has a light efficiency of 64.8 for red light, which is about 1% higher than that of Comparative Example 1.

Comparative Example 1, in which the main electrode layer includes Ag and does not include Li, has a light efficiency of 157.4 for green light. Example 1, in which the main electrode layer includes Ag and Li, has a light efficiency of 168.4 for green light, which is about 7% higher than that of Comparative Example 1.

Comparative Example 1, in which the main electrode layer includes Ag and does not include Li, has a light efficiency of 156.3 for blue light. Example 1, in which the main electrode layer includes Ag and Li, has a light efficiency of 175.1 for blue light, which is about 12% higher than that of Comparative Example 1. Thus, as described above, when the emission layer emits blue light and the main electrode layer includes Ag and Li, the main electrode layer reflects more light proceeding in a direction from the emission layer to the substrate (e.g., the −z direction). Thus, Example 1 has excellent or suitable light efficiency for blue light.

Although FIG. 5, illustrates that one emission layer is included in the intermediate layer 312, the present disclosure is not limited thereto. The intermediate layer 312 may include a plurality of emission layers. For example, the display element 310 may have a tandem structure. For example, the intermediate layer 312 may include a lower emission layer and an upper emission layer. The lower emission layer is arranged on the pixel electrode 311, and the upper emission layer may be arranged on the lower emission layer so as to overlap the lower emission layer. The upper emission layer may be to emit light of the same color as light emitted by the lower emission layer. The lower emission layer may form a first light-emitting unit, and the upper emission layer may form a second light-emitting unit.

In such cases, a charge generation layer (CGL) may be arranged between the lower emission layer and the upper emission layer. The CGL may serve to supply charges to the first light-emitting unit and the second light-emitting unit. Accordingly, the emission efficiency of the display element 310 having a structure in which a plurality of emission layers are stacked may be further increased. The charge generation layer may include an n-type (kind) charge generation layer for supplying electrons to the first light-emitting unit and a p-type (kind) charge generation layer for supplying holes to the second light-emitting unit. In one or more embodiments, an additional functional layer may be arranged between the lower emission layer and the charge generation layer, and the functional layer between the lower emission layer and the charge generation layer may include an electron transport material and/or an electron injection material. Additional functional layers may be arranged between the upper emission layer and the charge generation layer, and the functional layers between the upper emission layer and the charge generation layer may include a hole transport material and/or a hole injection material.

Above, the display apparatus 10 has been described, but the present disclosure is not limited thereto. The method of manufacturing the display apparatus 10 is also included in the scope of the present disclosure. Hereinafter, the method of manufacturing the display apparatus 10 is described.

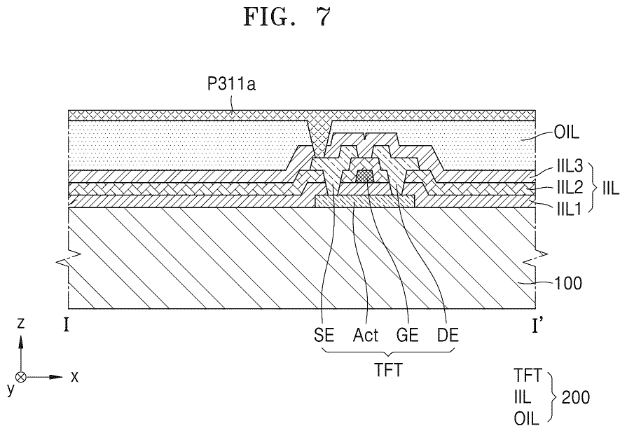

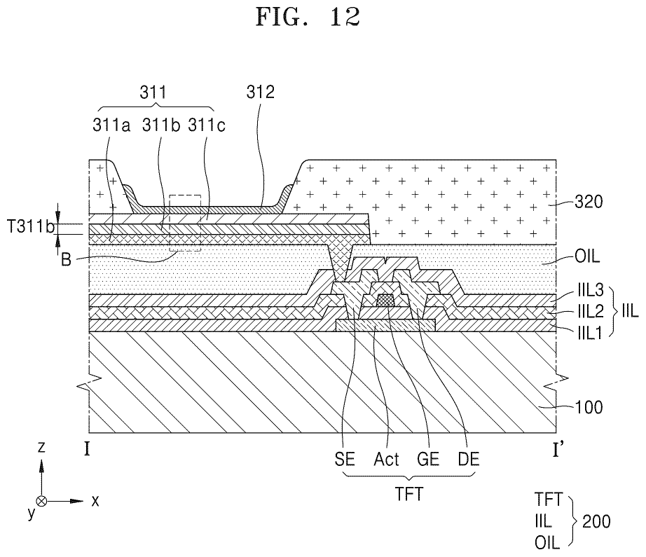

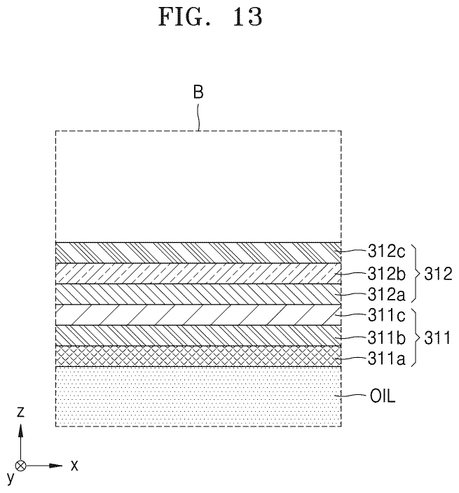

FIGS. 7 to 14 are cross-sectional views schematically illustrating part of the process of manufacturing the display apparatus 10 of FIG. 4, according to one or more embodiments of the present disclosure. For example, FIGS. 7 to 14 are cross-sectional views schematically illustrating the process of manufacturing the pixel electrode 311, the intermediate layer 312, and the counter electrode 313 of the display apparatus 10 of FIG. 4. In FIGS. 7 to 12 and 14, for convenience of explanation, a method of manufacturing the display apparatus 10 is described based on a cross-section of the display apparatus 10 taken along the line I-I′ of FIG. 2, according to one or more embodiments of the present disclosure. FIG. 13 is a cross-sectional view schematically illustrating an enlarged portion of the portion B of FIG. 12, according to one or more embodiments of the present disclosure. Hereinafter, in explaining the method of manufacturing the display apparatus 10 according to one or more embodiments with reference to FIGS. 7 to 14, because the reference numbers of FIGS. 7 to 14 that are substantially the same as those of FIGS. 4 and 5, redundant descriptions thereof may not be provided.

First, as illustrated in FIG. 7, a preliminary adhesive auxiliary layer P311a may be formed on the organic insulating layer OIL arranged on the substrate 100. In the present disclosure, “preliminary adhesive auxiliary layer” refers to a layer in which the shape of the adhesive auxiliary layer 311a is not patterned after depositing an adhesive layer forming material on the organic insulating layer OIL. The pixel circuit layer 200 may be arranged on the substrate 100. For example, before forming the preliminary adhesive auxiliary layer P311a on the substrate 100, the semiconductor layer Act may be formed on the substrate 100, and the gate insulating layer IIL1 may be formed on the semiconductor layer Act. Subsequently, the gate electrode GE may be formed on the gate insulating layer IIL1, and the first interlayer insulating layer IIL2 may be formed on the gate electrode GE. Subsequently, the source electrode SE and the drain electrode DE may be formed on the first interlayer insulating layer IIL2, and the second interlayer insulating layer IIL3 may be formed on the source electrode SE and the drain electrode DE. Subsequently, the organic insulating layer OIL may be formed on the second interlayer insulating layer IIL3. Accordingly, the organic insulating layer OIL may be arranged on the substrate 100, and a preliminary adhesive auxiliary layer P311a can be formed on the organic insulating layer OIL. Because the formation of the pixel circuit layer 200 may be a generally utilized and/or a generally available process in the manufacture of display apparatuses, a detailed description thereof may not be provided.

The preliminary adhesive auxiliary layer P311a may include a transparent conductive oxide. For example, the preliminary adhesive auxiliary layer P311a may include at least one of ITO, IZO, IGO, and/or IGZO. The thickness of the preliminary adhesive auxiliary layer P311a may be about 20 Å to about 150 Å. For example, the thickness of the preliminary adhesive auxiliary layer P311a may be 70 Å.

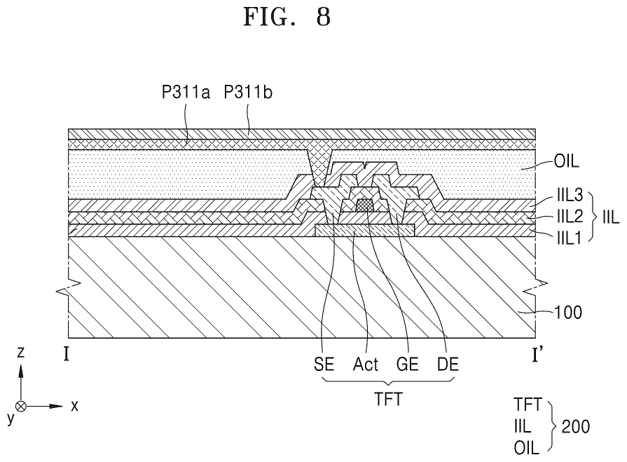

Subsequently, as illustrated in FIG. 8, a preliminary main electrode layer P311b may be formed on the preliminary adhesive auxiliary layer P311a. In the present disclosure, “preliminary main electrode layer” refers to a layer in which the shape of the main electrode layer 311b is not patterned after depositing a main electrode layer forming material on the preliminary adhesive auxiliary layer P311a.

The preliminary main electrode layer P311b may include Ag and Li. For example, the preliminary main electrode layer P311b may be formed by co-depositing Ag and Li on the preliminary adhesive auxiliary layer P311a. In one or more embodiments, the preliminary main electrode layer P311b may include Li in an amount of about 0.05 wt % to about 2.48 wt % based on the total weight of the main electrode layer P311b. The preliminary main electrode layer P311b may include Ag in an amount of about 97.52 wt % to about 99.95 wt % based on the total weight of the preliminary main electrode layer P311b.

When the preliminary main electrode layer P311b includes less than 0.05 wt % of Li based on the total weight of the preliminary main electrode layer P311b, the effect of doping Li may not be sufficient, and Ag of the main electrode layer 311b may be eluted. When the preliminary main electrode layer P311b includes more than 2.48 wt % of Li based on the total weight of the preliminary main electrode layer P311b, the amount of light reflected so as to be emitted from the front of the display apparatus and not proceed towards the substrate 100 may be reduced. Thus, if (e.g., when) the preliminary main electrode layer P311b includes more than 2.48 wt % of Li based on the total weight of the preliminary main electrode layer P311b, light efficiency of the display apparatus 10 may be reduced and/or low.

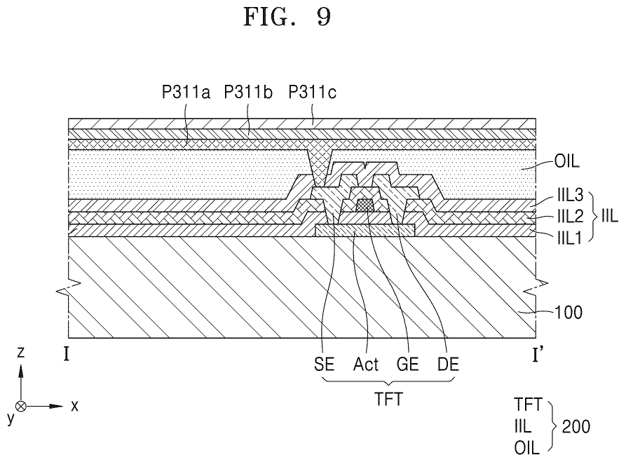

Subsequently, as illustrated in FIG. 9, a preliminary auxiliary electrode layer P311c may be formed on the preliminary main electrode layer P311b. In the present disclosure, “preliminary auxiliary electrode layer” refers to a layer in which the shape of the auxiliary electrode layer 311c is not patterned after depositing an auxiliary electrode layer forming material on the preliminary main electrode layer P311b.

The preliminary auxiliary electrode layer P311c may include a transparent conductive oxide. For example, the preliminary auxiliary electrode layer P311c may include at least one of ITO, IZO, IGO, and/or IGZO. The thickness of the preliminary auxiliary electrode layer P311c may be about 20 Å to about 150 Å. For example, the thickness of the preliminary auxiliary electrode layer P311c may be 50 Å.

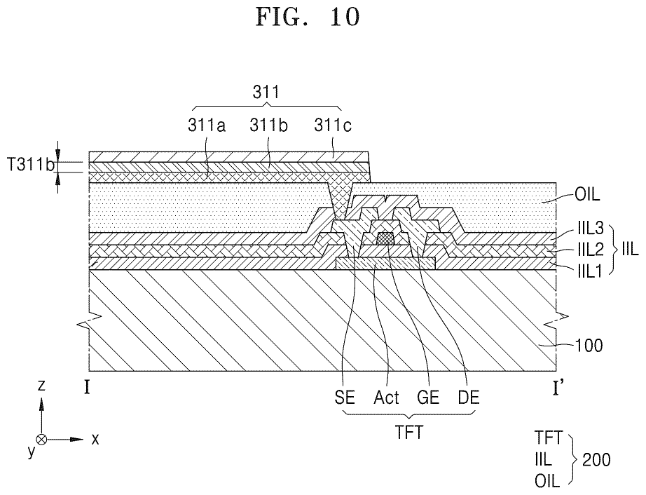

Next, as illustrated in FIG. 10, the preliminary adhesive auxiliary layer P311a, the preliminary main electrode layer P311b, and the preliminary auxiliary electrode layer P311c may be patterned. Accordingly, the pixel electrode 311 including the adhesive auxiliary layer 311a, the main electrode layer 311b, and the auxiliary electrode layer 311c may be formed. For example, by patterning the preliminary adhesive auxiliary layer P311a, the preliminary main electrode layer P311b, and the preliminary auxiliary electrode layer P311c, the pixel electrode 311 including the adhesive auxiliary layer 311a, the main electrode layer 311b, and the auxiliary electrode layer 311c may be formed.

In one or more embodiments, a thickness T311b of the main electrode layer 311b may be about 600 Å to about 1300 Å. When the thickness T311b of the main electrode layer 311b is less than 600 Å, the thickness T311b of the main electrode layer 311b may be thin, and the main electrode layer 311b may transmit, without reflecting, light traveling in the direction (e.g., the −z direction) from the emission layer 312b to the substrate 100. Thus, if (e.g., when) the thickness T311b of the main electrode layer 311b is less than 600 Å, light efficiency of the display apparatus 10 may be reduced and/or low. When the thickness T311b of the main electrode layer 311b exceeds 1,300 Å, the cost of manufacturing the display apparatus 10 is greater than if (e.g., when) the thickness T311b of the main electrode layer 311b is about 600 Å to about 1,300 Å, but the optical characteristics for both cases may be similar. Thus, if (e.g., when) the thickness T311b of the main electrode layer 311b exceeds 1,300 Å, the cost of manufacturing the display apparatus 10 may be inefficient and/or too high relative to the increase in the optical characteristics.

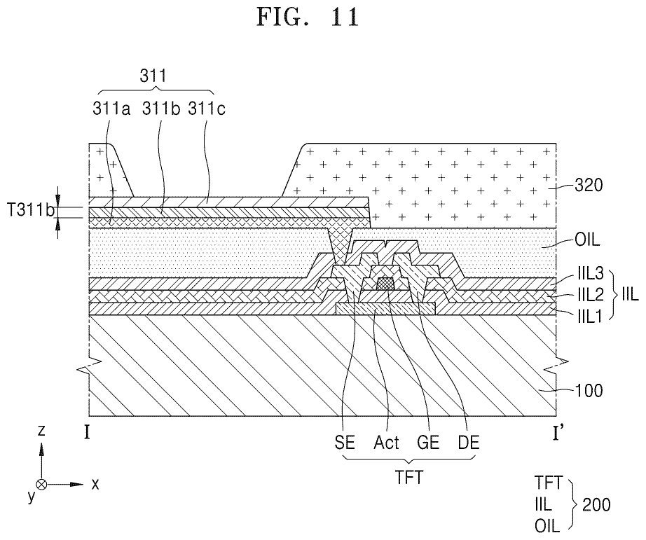

Subsequently, as illustrated in FIG. 11, the pixel-defining layer 320 may be formed on the pixel electrode 311. The pixel-defining layer 320 may include a pixel opening that exposes the central portion of the pixel electrode 311. For example, the pixel-defining layer 320 may be formed on the pixel electrode 311 and the organic insulating layer OIL, and may include the pixel opening. The pixel opening may expose the central portion of the pixel electrode 311. The pixel-defining layer 320 may include an organic material such as polyimide or HMDSO. In one or more embodiments, the pixel-defining layer 320 may include a light-blocking material. Because the formation of the pixel-defining layer 320 having a pixel opening may be a generally available and/or a generally utilized process in the manufacture of display apparatuses, a detailed description thereof may not be provided.

Subsequently, as illustrated in FIG. 12, the intermediate layer 312 may be formed on the auxiliary electrode layer 311c. As described above, the pixel opening of the pixel-defining layer 320 may expose the central portion of the pixel electrode 311, and at least a portion of the intermediate layer 312 may be located in the pixel opening. Accordingly, the intermediate layer 312 may be formed on the auxiliary electrode layer 311c of the pixel electrode 311.

As illustrated in FIG. 13, the intermediate layer 312 may include the emission layer 312b. The intermediate layer 312 may further include the hole transport layer 312a and the electron transport layer 312c. The hole transport layer 312a may be arranged between the pixel electrode 311 and the emission layer 312b, and the electron transport layer 312c may be arranged on the emission layer 312b. For example, the hole transport layer 312a may be formed on the auxiliary electrode layer 311c, the emission layer 312b may be formed on the hole transport layer 312a, and the electron transport layer 312c may be formed on the emission layer 312b. Because the hole transport layer 312a, the emission layer 312b, and the electron transport layer 312c have been described above in more detail with reference to FIG. 4, any duplicate description in this regard may not be provided. Because the formation of the intermediate layer 312 may be a generally available and/or generally utilized process in the manufacture of display apparatuses, a detailed description thereof may not be provided.

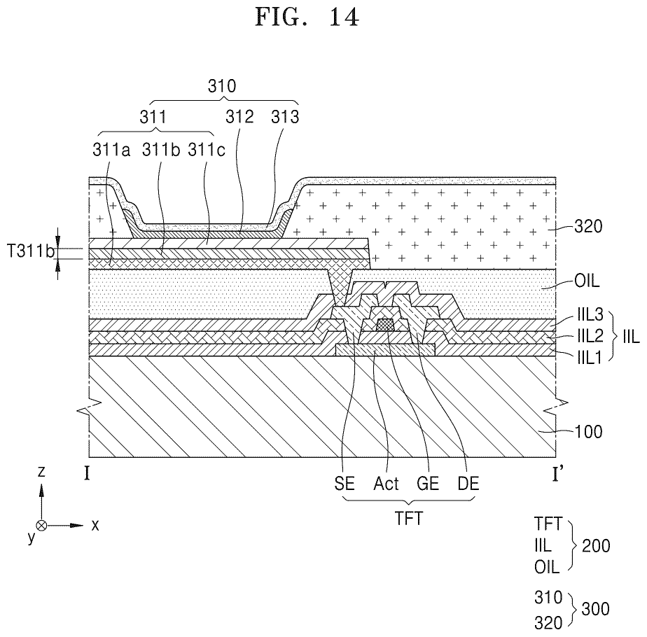

Subsequently, as shown in FIG. 14, the counter electrode 313 may be formed on the intermediate layer 312. For example, the counter electrode 313 may be formed on the intermediate layer 312 and the pixel-defining layer 320. The counter electrode 313 may include a light-transmitting conductive layer formed of ITO, In₂O₃, or IZO, and may include a semi-transmissive layer including a metal such as Al or Ag. For example, the counter electrode 313 may be a semi-transmissive layer including Mg or Ag. Because the formation of the counter electrode 313 may be a generally available and/or generally utilized process in the manufacture of display apparatuses, a detailed description thereof may not be provided.

According to one or more embodiments as described above, the display apparatus, the method of manufacturing the display apparatus, and the electronic apparatus in which the possibility of defects occurring during the manufacturing process may be reduced may be implemented.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” “approximately,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display apparatus comprising:
a substrate;
a pixel electrode on the substrate;
a counter electrode on the pixel electrode; and
an intermediate layer between the pixel electrode and the counter electrode and comprising an emission layer,
wherein the pixel electrode comprises a main electrode layer comprising silver (Ag) and lithium (Li).

2. The display apparatus of claim 1, wherein the main electrode layer comprises Li in an amount of 0.05 wt % to 2.48 wt % based on a total weight of the main electrode layer.

3. The display apparatus of claim 1, wherein the pixel electrode further comprises an auxiliary electrode layer between the main electrode layer and the intermediate layer.

4. The display apparatus of claim 3, wherein
the intermediate layer further comprises a hole transport layer between the pixel electrode and the emission layer and an electron transport layer between the emission layer and the counter electrode, and
the auxiliary electrode layer comprises a transparent conductive oxide.

5. The display apparatus of claim 1, further comprising an organic insulating layer between the substrate and the pixel electrode, wherein
the pixel electrode further comprises an adhesive auxiliary layer between the main electrode layer and the organic insulating layer,
the adhesive auxiliary layer comprises a transparent conductive oxide, and
the adhesive auxiliary layer is in direct contact with the organic insulating layer.

6. The display apparatus of claim 1, wherein a thickness of the main electrode layer is 600 Å to 1,300 Å.

7. The display apparatus of claim 1, wherein the emission layer is to emit blue light.

8. The display apparatus of claim 1, further comprising an encapsulation layer on the counter electrode and comprising at least one inorganic encapsulation layer and at least one organic encapsulation layer.

9. A method of manufacturing a display apparatus, the method comprising:
forming a preliminary adhesive auxiliary layer comprising a transparent conductive oxide on an organic insulating layer on a substrate;
forming a preliminary main electrode layer comprising silver (Ag) and lithium (Li) on the preliminary adhesive auxiliary layer;
forming a preliminary auxiliary electrode layer comprising the transparent conductive oxide on the preliminary main electrode layer;
forming a pixel electrode comprising an adhesive auxiliary layer, a main electrode layer, and an auxiliary electrode layer by patterning the preliminary adhesive auxiliary layer, the preliminary main electrode layer, and the preliminary auxiliary electrode layer;
forming a pixel-defining layer defining a pixel opening on the pixel electrode, the pixel opening exposing a central portion of the pixel electrode;
forming an intermediate layer comprising an emission layer on the auxiliary electrode layer; and
forming a counter electrode on the intermediate layer.

10. The method of claim 9, wherein the forming of the preliminary main electrode layer comprises forming the preliminary main electrode layer by co-depositing Ag and Li on the preliminary adhesive auxiliary layer.

11. The method of claim 9, wherein the preliminary main electrode layer comprises Li in an amount of 0.05 wt % to 2.48 wt % based on a total weight of the preliminary main electrode layer.

12. The method of claim 9, wherein the intermediate layer further comprises a hole transport layer between the pixel electrode and the emission layer and an electron transport layer on the emission layer.

13. The method of claim 9, wherein a thickness of the main electrode layer is 600 Å to 1,300 Å.

14. The method of claim 9, wherein the emission layer is to emit blue light.

15. An electronic apparatus comprising:
a processor; and
a display apparatus controlled by the processor, wherein the display apparatus comprises:
a substrate;
a pixel electrode on the substrate;
a counter electrode on the pixel electrode; and
an intermediate layer between the pixel electrode and the counter electrode and comprising an emission layer,
wherein the pixel electrode comprises a main electrode layer comprising silver (Ag) and lithium (Li).

16. The electronic apparatus of claim 15, wherein the main electrode layer comprises Li in an amount of 0.05 wt % to 2.48 wt % based on a total weight of the main electrode layer.

17. The electronic apparatus of claim 15, wherein the pixel electrode further comprises an auxiliary electrode layer between the main electrode layer and the intermediate layer.

18. The electronic apparatus of claim 17, wherein
the intermediate layer further comprises a hole transport layer between the pixel electrode and the emission layer and an electron transport layer between the emission layer and the counter electrode, and
the auxiliary electrode layer comprises a transparent conductive oxide.

19. The electronic apparatus of claim 15, further comprising an organic insulating layer between the substrate and the pixel electrode, wherein
the pixel electrode further comprises an adhesive auxiliary layer between the main electrode layer and the organic insulating layer,
the adhesive auxiliary layer comprises a transparent conductive oxide, and
the adhesive auxiliary layer is in direct contact with the organic insulating layer.

20. The electronic apparatus of claim 15, wherein the emission layer is to emit blue light.
